(19) United States
(12) Patent Application Publication
(10) Pub. No.: US 2026/0096088 A1
(43) Pub. Date: Apr. 2, 2026

(54) SEMICONDUCTOR MEMORY DEVICE

(71) Applicant: Samsung Electronics Co., Ltd., Suwon-si (KR)

(72) Inventor: SEOHA LEE, Suwon-si (KR)

(21) Appl. No.: 19/264,501

(22) Filed: Jul. 9, 2025

(30) Foreign Application Priority Data
Sep. 30, 2024 (KR) 10-2024-0133182

(51) Int. Cl. H10B 12/00; H01L 23/00; H01L 25/065; H01L 25/18; H10B 80/00

(52) U.S. Cl. CPC H10B 12/315; H10B 12/05; H10B 12/50; H10B 80/00; H10W 90/00; H10W 90/792

(57) ABSTRACT

A semiconductor device includes a lower dielectric layer that comprises a cell array region and a connection region that extends from the cell array region, a vertical channel pattern on the cell array region of the lower dielectric layer, a gate line on a lateral surface of the vertical channel pattern on the cell array region of the lower dielectric layer, a data storage pattern on the vertical channel pattern on the cell array region of the lower dielectric layer, and a dielectric pattern on the connection region of the lower dielectric layer. The vertical channel pattern and the dielectric pattern comprise the same dopant.

### CROSS-REFERENCE TO RELATED APPLICATION

This application claims priority under 35 U.S.C § 119 to Korean Patent Application No. 10-2024-0133182 filed on Sep. 30, 2024 in the Korean Intellectual Property Office, the disclosure of which is hereby incorporated by reference in its entirety.

### BACKGROUND

The present inventive concepts relate to a semiconductor memory device, and more particularly, to a semiconductor memory device including vertical channel transistors and a method of fabricating the same.

With the trend of reduction in design rule of a semiconductor memory device, the fabrication technology is being improved to increase integration, operating speed, and yield of the semiconductor memory device. Accordingly, transistors with vertical channels have been suggested to increase integration, conductance, or current driving capability.

### SUMMARY

Some embodiments of the present inventive concepts provide a semiconductor memory device having improved electrical properties and increased integration.

The object of the present inventive concepts is not limited to the mentioned above, and other objects which have not been mentioned above will be clearly understood to those skilled in the art from the following description.

According to some embodiments of the present inventive concepts, a semiconductor memory device may comprise: a lower dielectric layer that comprises a cell array region and a connection region that extends from the cell array region; a vertical channel pattern on the cell array region of the lower dielectric layer; a gate line on a lateral surface of the vertical channel pattern on the cell array region of the lower dielectric layer; a data storage pattern on the vertical channel pattern on the cell array region of the lower dielectric layer; and a dielectric pattern on the connection region of the lower dielectric layer. The vertical channel pattern and the dielectric pattern may comprise the same dopant.

According to some embodiments of the present inventive concepts, a semiconductor memory device may comprise: a lower dielectric layer that comprises a cell array region and a connection region that extends from the cell array region; a plurality of vertical channel patterns on the cell array region of the lower dielectric layer and spaced apart from each other in a first direction and a second direction; a plurality of gate lines that extend in the second direction and are spaced apart from each other in the first direction; a first dielectric pattern on the cell array region of the lower dielectric layer and in spaces between the vertical channel patterns that are adjacent to each other in the second direction; and a second dielectric pattern on the connection region of the lower dielectric layer. A material of the vertical channel patterns may be single-crystalline silicon comprising a dopant. The dopant may comprise at least one selected from carbon and boron.

According to some embodiments of the present inventive concepts, a semiconductor memory device may comprise: a peripheral circuit structure that comprises a plurality of peripheral circuit transistors; and a cell structure that vertically overlaps the peripheral circuit structure. The cell structure may comprise: a lower dielectric layer that comprises a cell array region and a connection region that extends from the cell array region; a plurality of bit lines in the cell array region of the lower dielectric layer; a plurality of vertical channel patterns on the cell array region of the lower dielectric layer and electrically connected to the bit lines; a plurality of gate lines in spaces between the vertical channel patterns on the cell array region of the lower dielectric layer; a dielectric pattern on the connection region of the lower dielectric layer; and a data storage pattern connected to a corresponding vertical channel pattern of the vertical channel patterns. The bit lines and the data storage pattern may be electrically connected to the peripheral circuit transistors of the peripheral circuit structure. The corresponding vertical channel pattern and the dielectric pattern may comprise the same dopant.

### BRIEF DESCRIPTION OF DRAWINGS

FIG. 1 illustrates a block diagram showing a semiconductor memory device according to some embodiments of the present inventive concepts.

FIGS. 2 and 3 illustrate perspective views showing a semiconductor memory device according to some embodiments of the present inventive concepts.

FIG. 4 illustrates a plan view showing a semiconductor memory device according to some embodiments of the present inventive concepts.

FIGS. 5A and 5B illustrate cross-sectional views respectively taken along lines A-A′ and B-B′ of FIG. 4, showing a semiconductor memory device according to some embodiments of the present inventive concepts.

FIG. 6A illustrates an enlarged view showing section X of FIG. 5A.

FIG. 6B illustrates an enlarged view showing section Y of FIG. 5B.

FIGS. 7, 8A and 8B, 9A and 9B, 10A and 10B, 11A and 11B, 12A and 12B, and 13A and 13B illustrate diagrams showing a method of fabricating a semiconductor memory device according to some embodiments of the present inventive concepts.

FIGS. 14, 15, 16, and 17 illustrate cross-sectional views taken along line A-A′ of FIG. 4, showing a semiconductor memory device according to some embodiments of the present inventive concepts.

### DETAILED DESCRIPTION OF EMBODIMENTS

The following will now describe some embodiments of the present inventive concepts with reference to the accompanying drawings. Like reference numerals may indicate like components throughout the description.

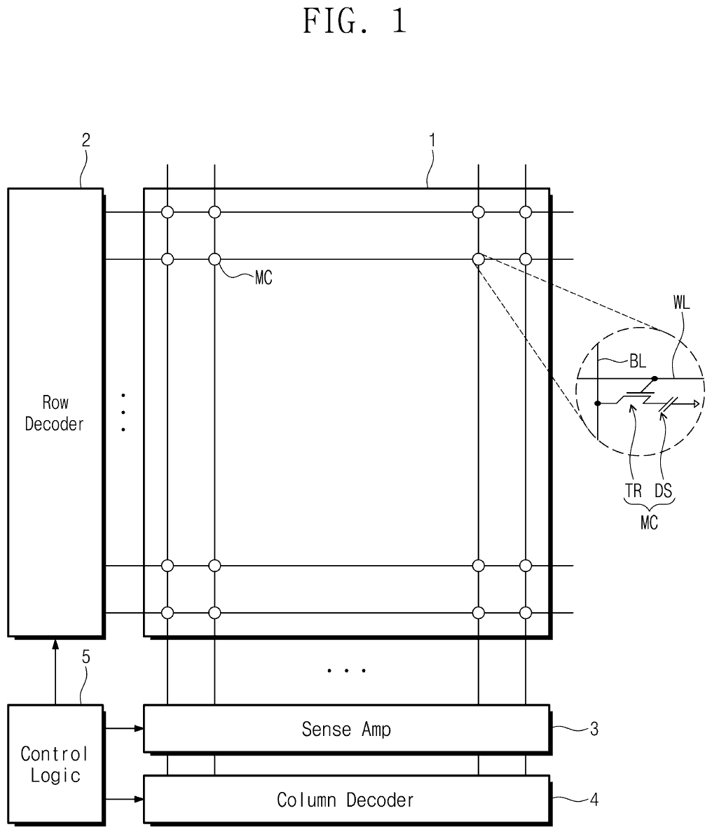

FIG. 1 illustrates a block diagram showing a semiconductor memory device according to some embodiments of the present inventive concepts.

Referring to FIG. 1, a semiconductor memory device may include a memory cell array 1, a row decoder 2, a sense amplifier 3, a column decoder 4, and a control logic 5.

The memory cell array 1 may include a plurality of memory cells MC that are two-dimensionally or three-dimensionally arranged. Each of the memory cells MC may be connected between a word line WL a bit line BL that intersect each other.

Each of the memory cells MC may include a selection device TR and a data storage device DS. The selection device TR and the data storage device DS may be electrically connected to each other. The selection device TR may be connected to a corresponding word line WL and a corresponding bit line BL. For example, the selection device TR may be positioned at an intersection where the word line WL and the bit line BL cross each other with a spacing therebetween.

The selection device TR may include a field effect transistor. The data storage device DS may include a capacitor, a magnetic tunnel junction pattern, or a variable resistor. For example, a gate terminal of the selection device TR may be connected to the word line WL, and source/drain terminals of the selection device TR may be connected to the bit line BL and the data storage device DS.

The row decoder 2 may decode an externally input address to select the word line WL of the memory cell array 1. The address decoded in the row decoder 2 may be provided to a row driver, and in response to control of control circuits, the row driver may provide the word line WL with a certain voltage.

In response to an address decoded from the column decoder 4, the sense amplifier 3 may detect and amplify a voltage difference of the bit line BL, and may then output the amplified voltage difference.

The column decoder 4 may provide a data path between the sense amplifier 3 and an external device (e.g., a memory controller). The column decoder 4 may decode an address input from an external and select the bit line BL.

The control logic 5 may generate control signals that control operations to write data to the memory cell array 1 and/or to read data from the memory cell array 1.

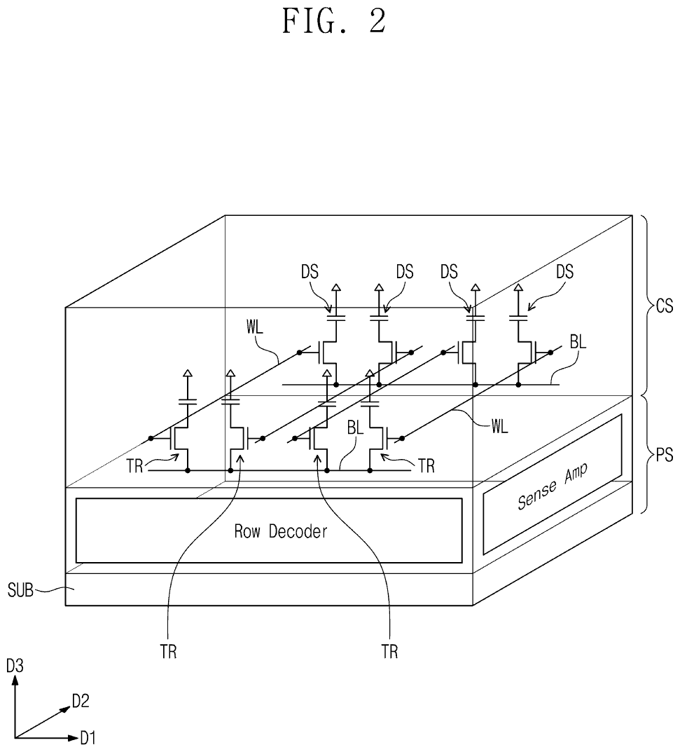

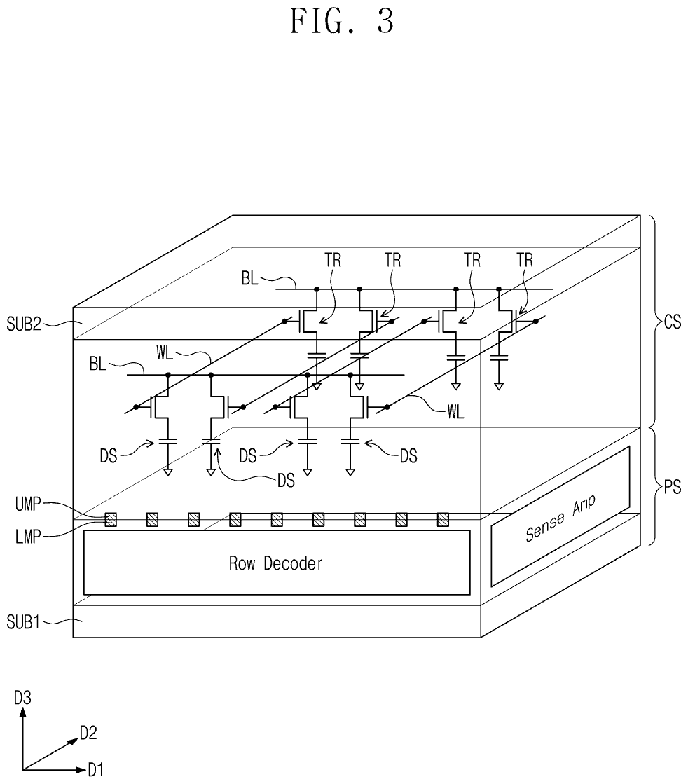

FIGS. 2 and 3 illustrate perspective views showing a semiconductor memory device according to some embodiments of the present inventive concepts.

Referring to FIGS. 2 and 3, a semiconductor memory device may include a peripheral circuit structure PS and a cell structure CS connected to the peripheral circuit structure PS.

The peripheral circuit structure PS may include core/peripheral circuits formed on a substrate SUB. The core/peripheral circuits may include the row decoder 2, the column decoder 4, the sense amplifier 3, and the control logics 5 that are discussed with reference to FIG. 1.

The cell structure CS may include a memory cell array 1 including memory cells MC that are arranged two-dimensionally or three-dimensionally discussed with reference to FIG. 1. As discussed above, each of the memory cells MC may include a selection device TR and a data storage device DS. For example, a vertical channel transistor (VCT) may be included as the selection device TR of each of the memory cells MC. The vertical channel transistor may include a channel whose lengthwise direction is perpendicular to a top surface of the substrate SUB. A capacitor may be included in the data storage device DS of each of the memory cells MC.

In an embodiment, the peripheral circuit structure PS may be provided on the substrate SUB, and the cell structure CS may be provided on the peripheral circuit structure PS. For example, the peripheral circuit structure PS may be first formed on the substrate SUB, and then the cell structure CS may be formed on the peripheral circuit structure PS. For another example, the cell structure CS may be first formed, and then the peripheral circuit structure PS may be formed.

In another embodiment, the peripheral circuit structure PS may be provided on a first substrate SUB1, and the cell structure CS may be provided on a second substrate SUB2. The first substrate SUB1 and the second substrate SUB2 may face each other. For example, the peripheral circuit structure PS and the cell structure CS may be respectively formed on the first substrate SUB1 and the second substrate SUB2, and then may be bonded to each other. The peripheral circuit structure PS may be provided with first metal pads LMP on an uppermost portion thereof. The first metal pads LMP may be electrically connected to core/peripheral circuits. The cell structure CS may be provided with second metal pads UMP on a lowermost portion thereof. The second metal pads UMP may be electrically connected to the memory cell array. The second metal pads UMP may contact or may be bonded to the first metal pads LMP of the peripheral circuit structure PS. The term “contact,” as used herein, refers to a direct connection (i.e., physical touching) unless the context indicates otherwise.

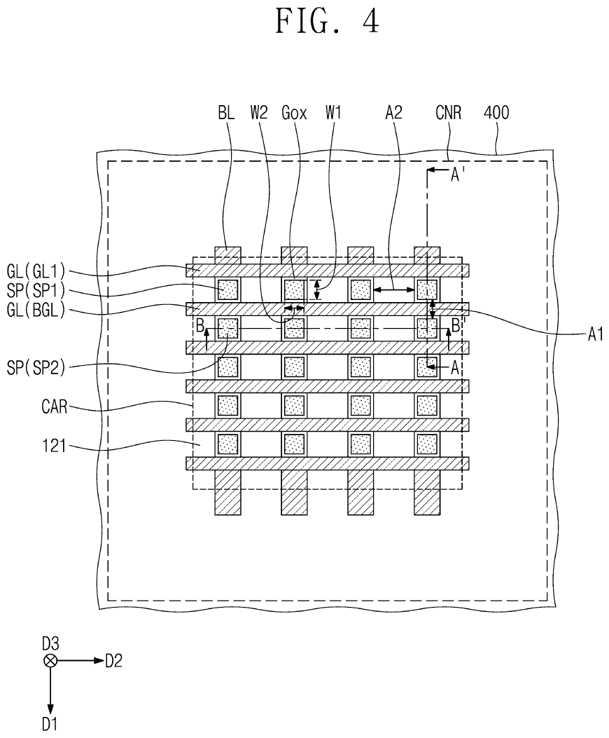

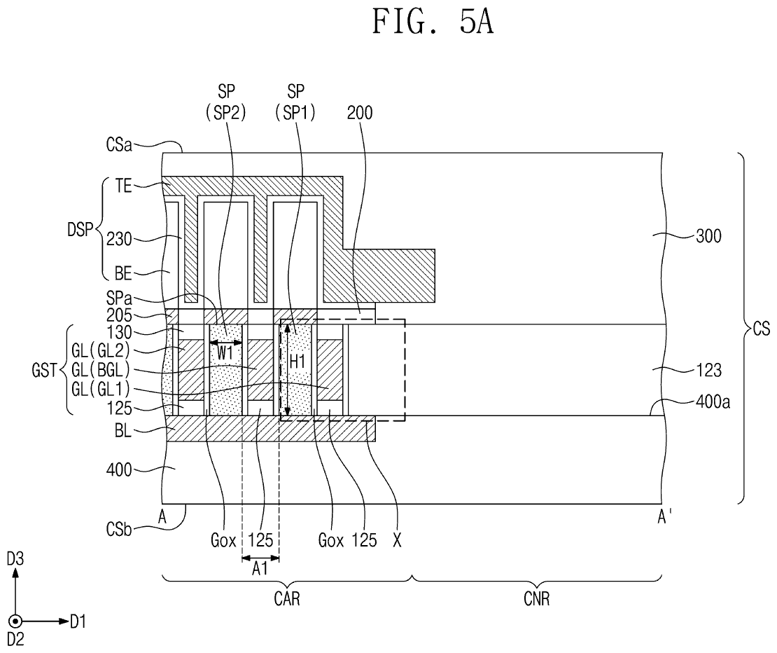

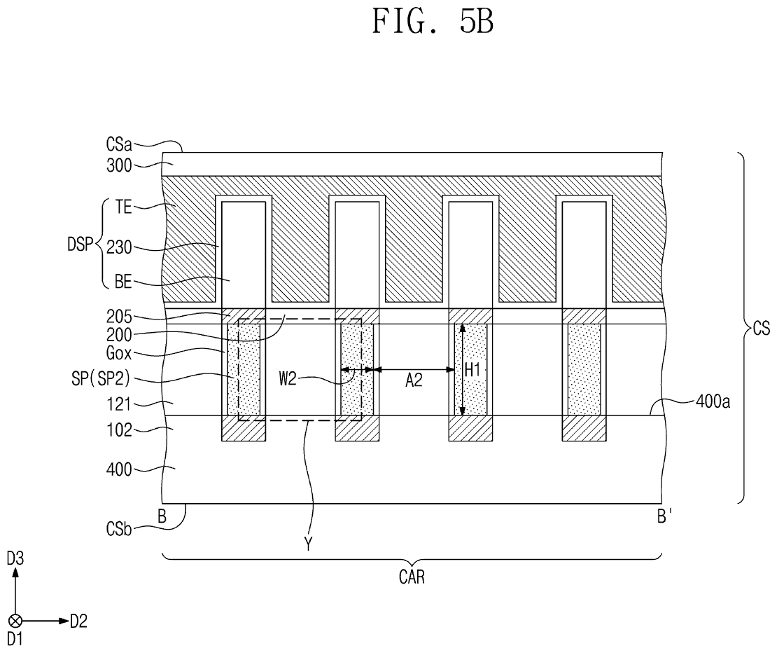

FIG. 4 illustrates a plan view showing a semiconductor memory device according to some embodiments of the present inventive concepts. FIGS. 5A and 5B illustrate cross-sectional views respectively taken along lines A-A′ and B-B′ of FIG. 4, showing a semiconductor memory device according to some embodiments of the present inventive concepts.

Referring to FIGS. 4, 5A, and 5B, a cell structure CS of a semiconductor memory device may be provided according to the present inventive concepts. The cell structure CS may include a lower dielectric layer 400 including a cell array region CAR and a connection region CNR. The lower dielectric layer 400 may extend in a first direction D1 and a second direction D2 from the cell array region CAR toward the connection region CNR. The first direction D1 and the second direction D2 may be parallel to a top surface 400a of the lower dielectric layer 400 and crossed with each other. In this description, the first direction D1 and the second direction D2 may be called a horizontal direction. A third direction D3 may be perpendicular to the top surface 400a of the lower dielectric layer 400. In this description, the third direction D3 may be called a vertical direction. For example, the first, second, and third directions D1, D2, and D3 may be orthogonal to each other.

The connection region CNR may extend in the first direction D1 and the second direction D2 from the cell array region CAR. When viewed in a plan view, the connection region CNR may surround the cell array region CAR. The present inventive concepts, however, are not limited thereto, and the connection region CNR may be disposed on one side of the cell array region CAR.

According to an embodiment, the lower dielectric layer 400 may be formed of a plurality of dielectric layers that are stacked in the third direction D3. For example, the lower dielectric layer 400 may have a multi-layered structure. The lower dielectric layer 400 may include a dielectric material, such as one or more of silicon oxide, silicon nitride, silicon oxynitride, and low-k dielectric (i.e., a low-k dielectric material).

Bit lines BL may be disposed in the cell array region CAR of the lower dielectric layer 400. Each of the bit lines BL may extend along the first direction D1. The bit lines BL may be spaced apart from each other in the second direction D2. A top surface of each of the bit lines BL may be coplanar with the top surface 400a of the lower dielectric layer 400. For example, the bit lines BL may include at least one selected from doped polysilicon, metal (e.g., Al, Cu, Ti, Ta, Ru, W, Mo, Pt, Ni, or Co), conductive metal nitride (e.g., TiN, TaN, WN, NbN, TiAlN, TiSiN, TaSiN, or RuTiN), conductive metal silicide, and conductive metal oxide (e.g., PtO, RuO₂, IrO₂, SRO(SrRuO₃), BSRO((Ba,Sr)RuO₃), CRO(CaRuO₃), or LSCo), but the present inventive concepts are not limited thereto. According to an embodiment, each of the bit lines BL may include a single layer or multiple layers of the materials mentioned above. Alternatively, the bit lines BL may include a two-dimensional semiconductor material such as graphene and carbon nano-tube.

Vertical channel patterns SP may be provided on the cell array region CAR of the lower dielectric layer 400. The vertical channel patterns SP may be disposed on the bit lines BL. For example, when viewed in a plan view, the vertical channel patterns SP may overlap the bit lines BL. Bottom surfaces of the vertical channel patterns may contact the top surfaces of the bit lines BL. Thus, the vertical channel patterns SP may be connected to the bit lines BL. The vertical channel patterns SP may be spaced apart from each other in the first direction D1 and the second direction D2 on the bit lines BL. For example, the vertical channel patterns SP may be two-dimensionally arranged on the cell array region CAR of the lower dielectric layer 400. Each of the vertical channel patterns SP may have a first width W1 in the first direction D1 and a second width W2 in the second direction D2. Each of the vertical channel patterns SP may have a first height H1 in the third direction D3. Each of the vertical channel patterns SP may have a shape that extends in the third direction D3 perpendicular to the top surface 400a of the lower dielectric layer 400. For example, the vertical channel patterns SP may include a first vertical channel pattern SP1 and a second vertical channel pattern SP2.

According to the present inventive concepts, in the following method of fabricating a semiconductor device, the vertical channel patterns SP may be formed by an epitaxial growth process on a doped seed layer. Therefore, a material of the vertical channel patterns SP may be high-quality single-crystalline silicon. In conclusion, a semiconductor memory device may improve in reliability and electrical properties.

Gate structures GST may be provided on the cell array region CAR of the lower dielectric layer 400. Each of the gate structures GST may extend in the second direction D2. The gate structures GST may be spaced apart from each other in the first direction D1. The gate structures GST may be disposed adjacent to the vertical channel patterns SP. For example, each of the gate structures GST may be positioned between the vertical channel patterns SP that are adjacent to each other in the first direction D1. Each of the gate structures GST may include a gate line GL, a first buried layer 125, and a second buried layer 130. According to an embodiment, the gate lines GL may include a first gate line GL1, a second gate line GL2, and a back-gate line BGL. For example, the back-gate line BGL and the first gate line GL1 may serve as a gate line of a transistor. The back-gate line BGL and the second gate line GL2 may serve as a gate line of another transistor. The back-gate line BGL may be shared by two adjacent transistors.

The vertical channel patterns SP may be disposed adjacent to the gate lines GL. The gate lines GL may be spaced apart in the third direction D3 from the bit lines BL. In an embodiments, the first vertical channel pattern SP1 may be positioned adjacent to the first gate line GL1. The second vertical channel pattern SP2 may be positioned adjacent to the second gate line GL2. For example, two adjacent vertical channel patterns SP of the first vertical channel pattern SP1 and the second vertical channel pattern SP2 may be spaced apart by a first distance A1 in the first direction D1. Two adjacent vertical channels SP may be spaced apart by a second distance A2 in the second direction D2. For example, the vertical channel patterns SP may be spaced apart by the first distance A1 in the first direction D1 and by the second distance A2 in the second direction D2.

The back-gate line BGL may be positioned between the first vertical channel pattern SP1 and the second vertical channel pattern SP2. The first vertical channel pattern SP1 may be positioned between the first gate line GL1 and the back-gate line BGL. The second vertical channel pattern SP2 may be positioned between the back-gate line BGL and the second gate line GL2. Each of the first gate line GL1, the second gate line GL2, and the back-gate line BGL may extend in the second direction D2 while extending across the bit line BL. According to an embodiment, the back-gate line BGL may be omitted, and the semiconductor memory device may have a single gate transistor structure.

The first gate line GL1, the second gate line GL2, and the back-gate line BGL may include doped polysilicon, metal, conductive metal nitride, conductive metal silicide, conductive metal oxide, or a combination thereof. For example, the gate lines GL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but the present inventive concepts are not limited thereto.

The first buried layer 125 may be positioned between a bottom surface of each of the gate lines GL and the top surface of each of the bit lines BL. The second buried layer 130 may be positioned on a top surface of each of the gate lines GL. For example, the first and second buried layers 125 and 130 may include a dielectric material, such as one or more of silicon oxide, silicon nitride, silicon oxynitride, and low-k dielectric.

A gate dielectric layer Gox may be provided between the gate structures GST and the vertical channel patterns SP. For example, the gate dielectric layer Gox may be positioned between the vertical channel patterns SP and the gate lines GL of the gate structures GST. The gate dielectric layer Gox may extend between the first buried layer 125 and the vertical channel patterns SP and between the second buried layer 130 and the vertical channel patterns SP. The gate dielectric layer Gox may contact sidewalls of the vertical channel patterns SP. When viewed in a plan view, the gate dielectric layer Gox may surround each of the vertical channel patterns SP. According to an embodiment, the gate dielectric layer Gox may be provided only the sidewalls of the vertical channel patterns SP, which sidewalls face the gate lines GL. When viewed in a plan view, the gate dielectric layer Gox may not surround each of the vertical channel patterns SP. The gate dielectric layer Gox may be formed of silicon oxide, silicon oxynitride, silicon nitride, high-k dielectric, or a combination thereof. In this description, the high-k dielectric may be a material whose dielectric constant is greater than that of silicon oxide. For example, the high-k dielectric may include HfO₂, HfSiO, HfSiON, HfTaO, HfTiO, HfZrO, ZrO₂, Al₂O₃, or a combination thereof.

Each of first dielectric patterns 121 may be positioned between the vertical channel patterns SP that are adjacent to each other in the second direction D2. Each of first dielectric patterns 121 may be positioned between the gate lines GL that are adjacent to each other in the first direction D1. The first dielectric patterns 121 may be positioned between the vertical channel patterns SP and the gate lines GL. A bottom surface of each of the first dielectric patterns 121 may contact the top surface 400a of the lower dielectric layer 400. For example, the first dielectric patterns 121 may include a dielectric material, such as one or more of silicon oxide, silicon nitride, silicon oxynitride, and low-k dielectric.

A second dielectric pattern 123 may be provided on the lower dielectric layer 400 on the connection region CNR of the lower dielectric layer 400. A bottom surface of the second dielectric pattern 123 may contact the top surface 400a of the lower dielectric layer 400. The second dielectric pattern 123 may contact the gate structures GST adjacent to the connection region CNR. When viewed in a plan view, the second dielectric pattern 123 may surround the vertical channel patterns SP and the gate structures GST. For example, the second dielectric pattern 123 may include substantially the same material, such as one or more of silicon oxide, silicon nitride, silicon oxynitride, and low-k dielectric, as that of the first dielectric patterns 121. According to an embodiment, the second dielectric pattern 123 may be formed simultaneously with the first dielectric patterns 121.

On the cell array region CAR of the lower dielectric layer 400, an interlayer dielectric layer 200 may be provided on the gate structures GST. The interlayer dielectric layer 200 may contact the second buried layer 130 of each of the gate structures GST. The interlayer dielectric layer 200 adjacent to the connection region CNR may extend onto a portion of a top surface of the second dielectric pattern 123.

Capacitor contacts 205 may be provided on the vertical channel patterns SP. The capacitor contacts 205 may be positioned in the interlayer dielectric layer 200. Each of the capacitor contacts 205 may contact a top surface SPa of a corresponding vertical channel pattern SP. When viewed in a plan view, the capacitor contacts 205 may vertically overlap the vertical channel patterns SP. The capacitor contacts 205 may have top surfaces coplanar with that of the interlayer dielectric layer 200. For example, the capacitor contacts 205 may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof.

A data storage pattern DSP may be provided on the interlayer dielectric layer 200. The data storage pattern DSP may be electrically connected through the capacitor contacts 205 to the vertical channel patterns SP. For example, the data storage pattern DSP may include bottom electrodes BE that are spaced apart from each other in a horizontal direction, a capacitor dielectric layer 230 that covers the bottom electrodes BE, and a top electrode TE that covers the capacitor dielectric layer 230. For example, the capacitor dielectric layer 230 may be positioned between the bottom electrodes BE and the top electrode TE. The data storage pattern DSP may constitute a capacitor.

According to an embodiment, the data storage pattern DSP may include a magnetic tunnel junction pattern of a magnetic random access memory (MRAM). According to another example, the data storage pattern DSP may include a phase change material or a variable resistance material of a phase-change random access memory (PRAM) or a resistive random access memory (ReRAM). This is, however, merely exemplary, and the present inventive concepts are not limited thereto. The data storage pattern DSP may include various structures and/or materials capable of storing data.

A first upper dielectric layer 300 may be provided to cover the data storage pattern DSP on the cell array region CAR and the second dielectric pattern 123 on the connection region CAR. The first upper dielectric layer 300 may contact the second dielectric pattern 123 and the top electrode TE of the data storage pattern DSP. A top surface CSa of the first upper dielectric layer 300 may be opposite to a bottom surface CSb of the lower dielectric layer 400 in the third direction D3. The first upper dielectric layer 300 may include a dielectric material, such as one or more of silicon oxide, silicon nitride, silicon oxynitride, and low-k dielectric. According to an embodiment, the first upper dielectric layer 300 may include substantially the same material as that of the second dielectric pattern 123. An invisible interface may be provided between the first upper dielectric layer 300 and the second dielectric pattern 123.

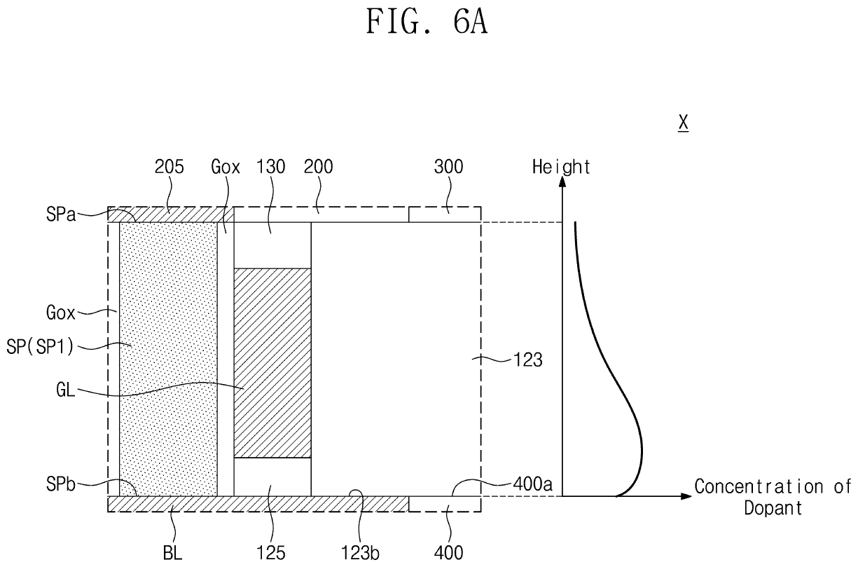

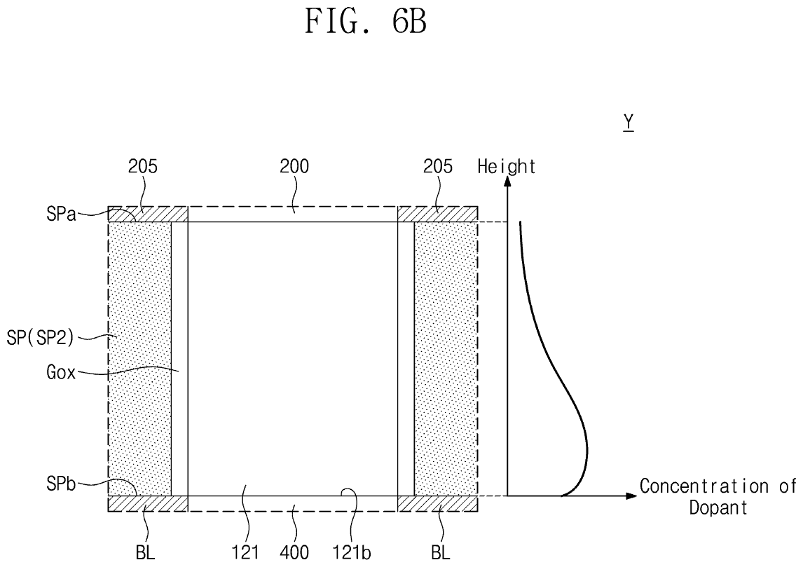

FIG. 6A illustrates an enlarged view showing section X of FIG. 5A. FIG. 6B illustrates an enlarged view showing section Y of FIG. 5B.

Referring to FIGS. 6A and 6B, the vertical channel patterns SP, the first dielectric pattern 121, and the second dielectric pattern 123 may be formed on a doped seed layer in the following method of fabricating a semiconductor memory device. The seed layer may be removed in the procedure for fabricating a semiconductor memory device. The bit line BL and the lower dielectric layer 400 may be formed in a space from which the seed layer is removed.

According to some embodiments of the present inventive concepts, a dopant of the seed layer may diffuse into the vertical channel patterns SP, the first dielectric pattern 121, and the second dielectric pattern 123 in the procedure for fabricating a semiconductor memory device. Thus, the dopant may be present in the vertical channel patterns SP, the first dielectric pattern 121, and the second dielectric pattern 123. The vertical channel patterns SP, the first dielectric pattern 121, and the second dielectric pattern 123 may include the same dopant. For example, the dopant may include at least one selected from carbon (C) and boron (B).

As each of the vertical channel patterns SP has a shape that extends in the vertical direction, the vertical channel pattern SP may have a top surface SPa and a bottom surface SPb that are opposite to each other in the vertical direction. A concentration of the dopant in the vertical channel pattern SP may decrease in the vertical direction from the bottom surface SPb toward the top surface SPa of the vertical channel pattern SP. For example, the concentration of the dopant may decrease with an increasing distance from the bottom surface SPb of each of the vertical channel patterns SP toward the top surface SPa thereof. For more detail, the concentration of the dopant may increase and then decrease in the vertical direction from the bottom surface SPb toward the top surface SPa of each of the vertical channel patterns SP. For example, the concentration of the dopant may have a maximum value at a location adjacent to the bottom surface SPb of each of the vertical channel patterns SP.

The present inventive concepts, however, are not limited thereto. According to an embodiment, the concentration of the dopant may linearly decrease in a direction from the bottom surface SPb toward the top surface SPa of each of the vertical channel patterns SP. According to another embodiment, the concentration of the dopant may be uniform in the vertical channel patterns SP so that the concentration of the dopant may be substantially the same at both of the top surface SPa and the bottom surface SPb of each of the vertical channel patterns SP.

The concentration of the dopant in the first dielectric pattern 121 and the second dielectric pattern 123 may have a profile substantially the same as that of the concentration of the dopant in the vertical channel patterns SP. For example, the concentration of the dopant may decrease with an increasing distance from a bottom surface 121b of the first dielectric pattern 121 and a bottom surface 123b of the second dielectric pattern 123. The present inventive concepts, however, are not limited thereto.

The concentration of the dopant may be changed depending on height of each of the vertical channel pattern SP, the first dielectric pattern 121, and the second dielectric pattern 123. For example, the concentration of the dopant may decrease with an increase in height of each of the vertical channel pattern SP, the first dielectric pattern 121, and the second dielectric pattern 123. In this description, the term “height” may refer to a length in a direction perpendicular to the top surface of the bit line BL and the top surface 400a of the lower dielectric layer 400.

According to an embodiment, a dopant may also be present in the gate line GL. For example, a concentration of the dopant in the gate line GL may have a profile substantially the same as that of the dopant concentration of the vertical channel patterns SP.

In the following method of fabricating a semiconductor memory device, the vertical channel patterns SP, the first dielectric pattern 121, and the second dielectric pattern 123 may be formed on a seed layer having a flat top surface. The vertical channel patterns SP, the first dielectric pattern 121, and the second dielectric pattern 123 may contact the flat top surface of the seed layer. Thus, the bottom surface SPb of each of the vertical channel patterns SP, the bottom surface 121b of the first dielectric pattern 121, and the bottom surface 123b of the second dielectric pattern 123 may be positioned on the same plane.

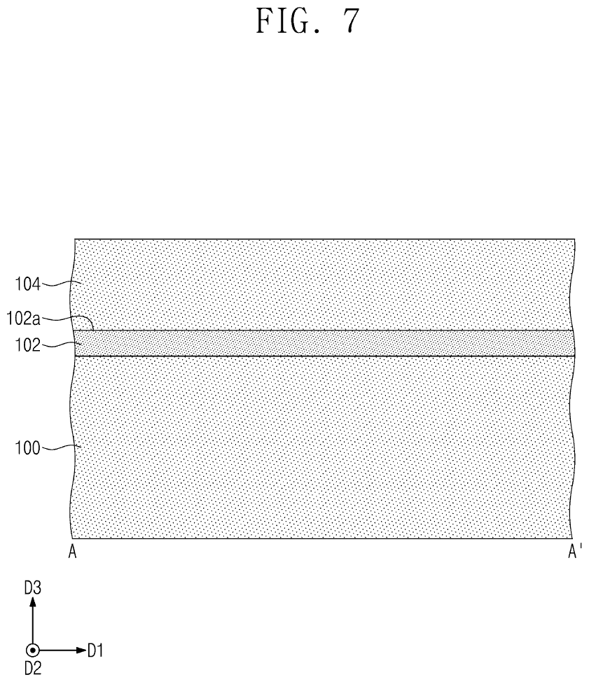

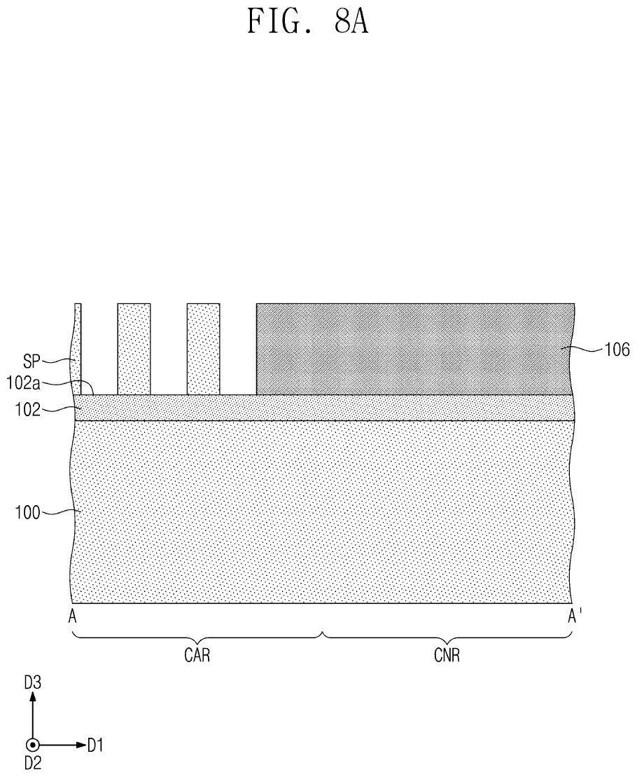

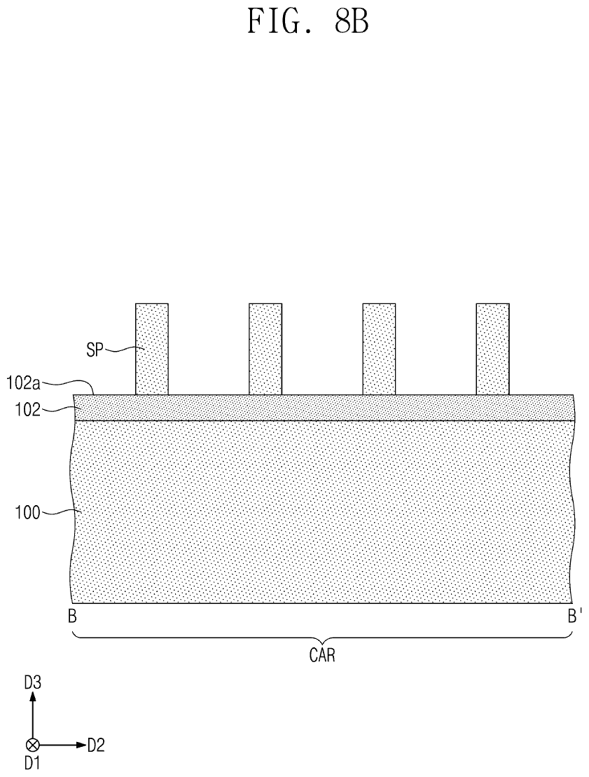

FIGS. 7 to 13B illustrate diagrams showing a method of fabricating a semiconductor memory device according to some embodiments of the present inventive concepts. FIGS. 7, 8A, 9A, 10A, 11A, 12A, and 13A are diagrams taken along line A-A′ of FIG. 4. FIGS. 8B, 9B, 10B, 11B, 12B, and 13B are diagrams taken along line B-B′ of FIG. 4.

Referring to FIG. 7, a substrate 100 may be provided. For example, the substrate W may include a silicon (Si) wafer. A seed layer 102 may be formed on the substrate 100. The seed layer 102 may have a flat top surface 102a. For example, the top surface 102a of the seed layer 102 may be parallel to a first direction D1 and a second direction D2. The seed layer 102 may be formed by an epitaxial growth process. The epitaxial growth process may include a chemical vapor deposition (CVD) process and/or a molecular beam epitaxy (MBE) process. The seed layer 102 may include a material having etch selectivity with respect to the substrate 100 and a semiconductor layer 104 which will be discussed below. For example, the seed layer 102 may include silicon-germanium (SiGe).

A dopant may be introduced into the seed layer 102, such that the seed layer 102 may include the dopant. For example, the dopant may include at least one selected from carbon (C) and boron (B). According to an embodiment, the dopant may be in-situ introduced during the epitaxial growth process for forming the seed layer 102. According to another embodiment, the dopant may be introduced after the formation of the seed layer 102.

The semiconductor layer 104 having a uniform thickness may be formed on the seed layer 102. The semiconductor layer 104 may have a large thickness on the seed layer 102. The thickness of the semiconductor layer 104 may be substantially the same as that of vertical channel patterns SP which will be discussed below. The semiconductor layer 104 may be formed by an epitaxial growth process in which the seed layer 102 is used as a seed. Unlike the seed layer 102, no dopant may be introduced into the semiconductor layer 104. For example, the semiconductor layer 104 may include silicon (Si), for example, single-crystalline silicon.

According to the present inventive concepts, the dopant in the seed layer 102 may reduce lattice mismatch between the silicon (Si) and germanium (Ge). For example, when the semiconductor layer 104 is formed on the seed layer 102 doped with the dopant such as boron and carbon, a lattice mismatch between the seed layer 102 and the semiconductor layer 104 may be reduced. Therefore, it may be possible to reduce lattice defects of the semiconductor layer 104 which is formed on the seed layer 102. Accordingly, a high-quality semiconductor layer 104 may be easily formed.

Referring to FIGS. 8A and 8B, the substrate 100 may include a cell array region CAR and a connection region CNR. Vertical channel patterns SP may be formed on the cell array region CAR of the substrate 100. The formation of the vertical channel patterns SP may include forming a mask pattern on the semiconductor layer 104, performing an anisotropic etching process in which the mask pattern is used as an etching mask to pattern the semiconductor layer 104, and removing the mask pattern.

Since the vertical channel patterns SP are formed from the semiconductor layer 104, each of the vertical channel patterns SP may be single-crystalline silicon. The vertical channel patterns SP may be spaced apart from each other in the first direction D1 and the second direction D2. Each of the vertical channel patterns SP may contact a top surface 102a of the seed layer 102. For example, a bottom surface of each of the vertical channel patterns SP and the top surface 102a of the seed layer 102 may be positioned on the same plane.

As the seed layer 102 has etch selectivity with respect to the semiconductor layer 104, the seed layer 102 may serve as an etch stop layer in an anisotropic etching process for forming the vertical channel patterns SP. With the seed layer 102 as an etch stop layer, the semiconductor layer 104 may be over-etched so that the vertical channel patterns SP may be separated from each other without causing damage on the substrate 100 due to such over-etching.

Afterwards, a sacrificial layer 106 may be formed on the connection region CNR of the substrate 100. The sacrificial layer 106 may be positioned on the seed layer 102. The sacrificial layer 106 may cover a portion of the top surface 102a of the seed layer 102. The sacrificial layer 106 may be spaced apart in a horizontal direction from the vertical channel patterns SP. For example, the sacrificial layer 106 may include a spin-on-hardmask (SOH) layer or an amorphous carbon layer (ACL), but the present inventive concepts are not limited thereto.

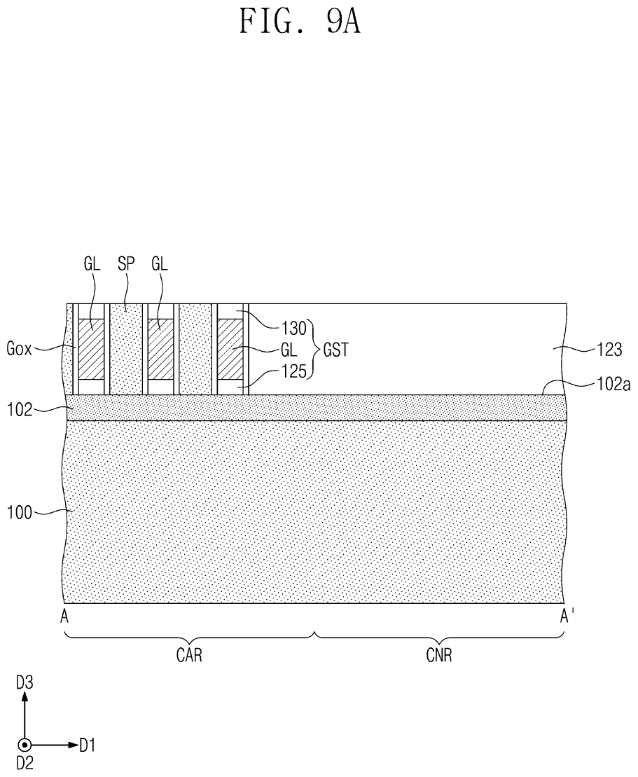

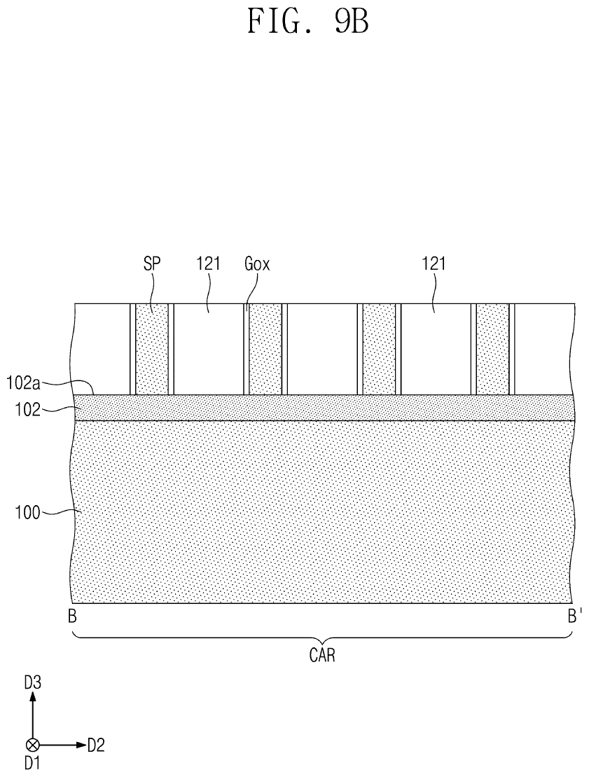

Referring to FIGS. 9A and 9B, a first buried layer 125, a second buried layer 130, gate lines GL, a gate dielectric layer Gox, and first dielectric patterns 121 may be formed on the cell array region CAR of the substrate 100, and a second dielectric pattern 123 may be formed on the connection region CNR of the substrate 100.

The gate dielectric layer Gox may be formed to surround sidewalls of each of the vertical channel patterns SP. When viewed in a plan view, the gate dielectric layer Gox may surround each of the vertical channel patterns SP. The gate dielectric layer Gox may be conformally formed by a chemical vapor deposition (CVD) process or an atomic layer deposition (ALD) whose a step coverage is excellent.

The first buried layer 125, the gate lines GL, and the second buried layer 130 may be sequentially formed between the vertical channel patterns SP. The first buried layer 125, the gate lines GL, and the second buried layer 130 may be formed by a film formation technique, such as chemical vapor deposition (CVD) and physical vapor deposition (PVD). Thus, gate structures GST may be formed each of which includes the first buried layer 125, the gate line GL, and the second buried layer 130.

After the formation of the gate structures GST, the sacrificial layer 106 may be removed from the connection region CNR of the substrate 100. After the removal of the sacrificial layer 106, a dielectric material may be deposited on a front surface of the substrate 100. The dielectric material may cover the seed layer 102, the vertical channel patterns SP, and the second buried layer 130. Thereafter, the dielectric material may undergo a planarization process to expose again the vertical channel patterns SP and the second buried layer 130. Thus, the dielectric material may be formed into the first dielectric patterns 121 and the second dielectric pattern 123. The first dielectric patterns 121 and the second dielectric pattern 123 may have bottom surfaces located on the same plane on which the top surface 102a of the seed layer 102 is positioned. For example, the first dielectric patterns 121 and the second dielectric pattern 123 may be formed simultaneously with each other, but the present inventive concepts are not limited thereto.

According to some embodiments of the present inventive concepts, the vertical channel patterns SP, the first dielectric patterns 121, and the second dielectric pattern 123 may be formed on the seed layer 102 having the flat top surface 102a parallel to the first direction D1 and the second direction D2. Thus, the vertical channel patterns SP, the first dielectric patterns 121, and the second dielectric pattern 123 may have bottom surfaces positioned on the same plane.

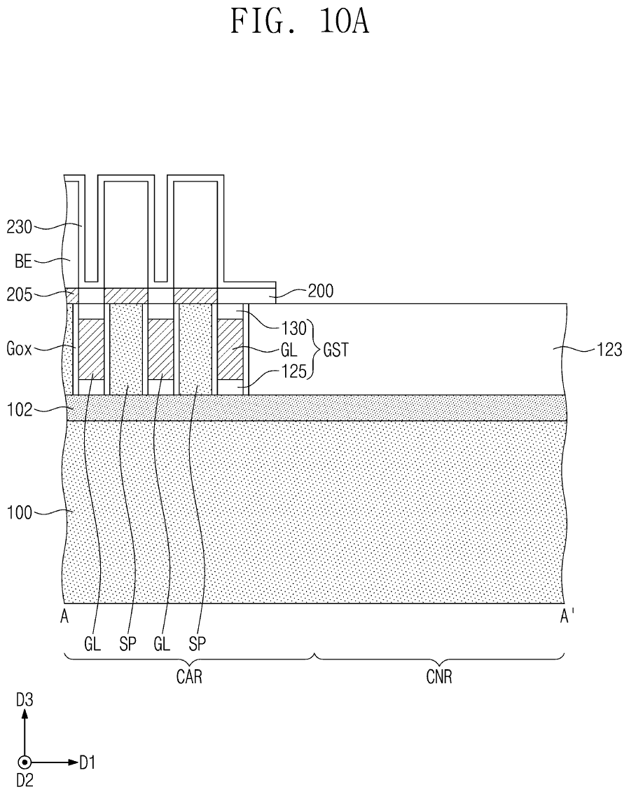

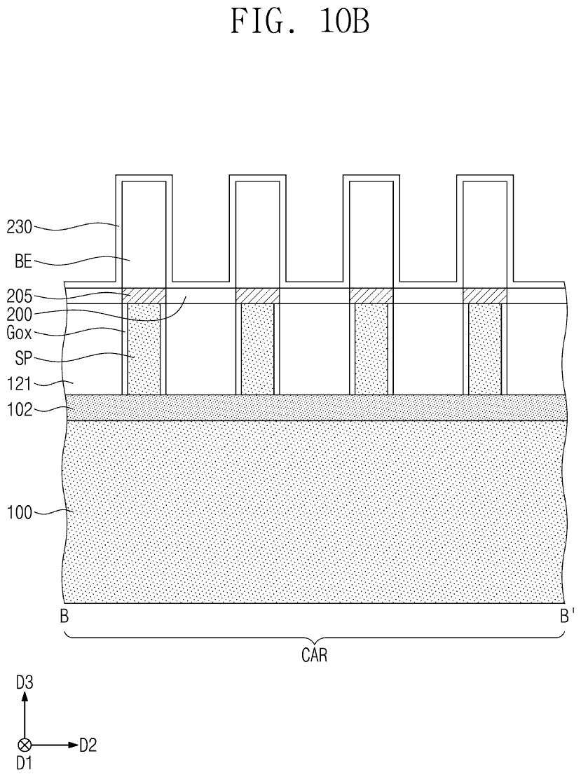

Referring to FIGS. 10A and 10B, an interlayer dielectric layer 200 having a uniform thickness may be formed on the cell array region CAR of the substrate 100. The interlayer dielectric layer 200 may cover the second buried layer 130 and the first dielectric patterns 121. The interlayer dielectric layer 200 may cover a portion of the second dielectric pattern 123, but the present inventive concepts are not limited thereto.

Capacitor contacts 205 may be formed in the interlayer dielectric layer 200, and bottom electrodes BE may be correspondingly formed on the capacitor contacts 205. The formation of the bottom electrodes BE may include forming a bottom electrode layer and patterning the bottom electrode layer. Each of the bottom electrodes BE may have a shape that extends in a third direction D3, and the bottom electrodes BE may be spaced apart from each other in a horizontal direction.

A capacitor dielectric layer 230 may be formed on the bottom electrodes BE. The capacitor dielectric layer 230 may have a uniform thickness that covers the bottom electrodes BE and the interlayer dielectric layer 200. The capacitor dielectric layer 230 may be conformally formed by a chemical vapor deposition (CVD) process or an atomic layer deposition (ALD) whose a step coverage is excellent.

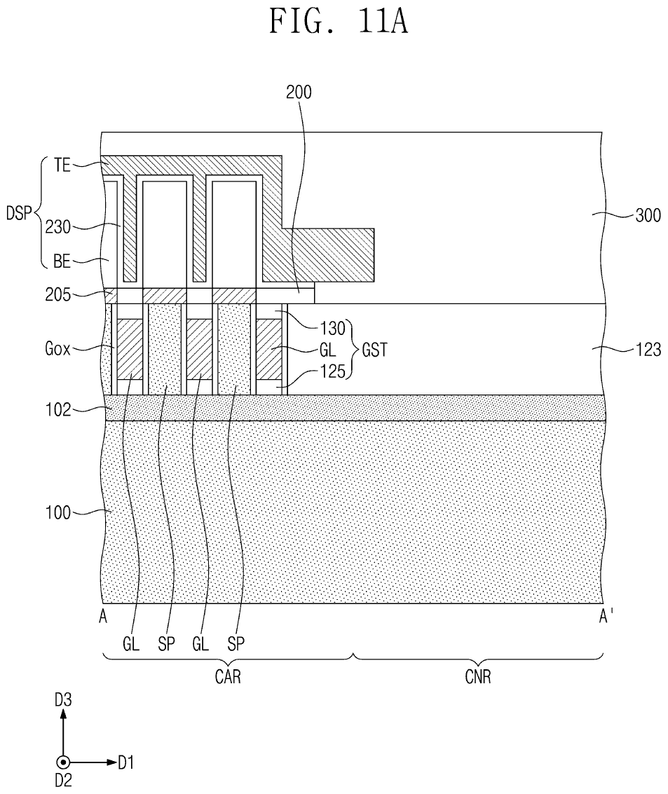

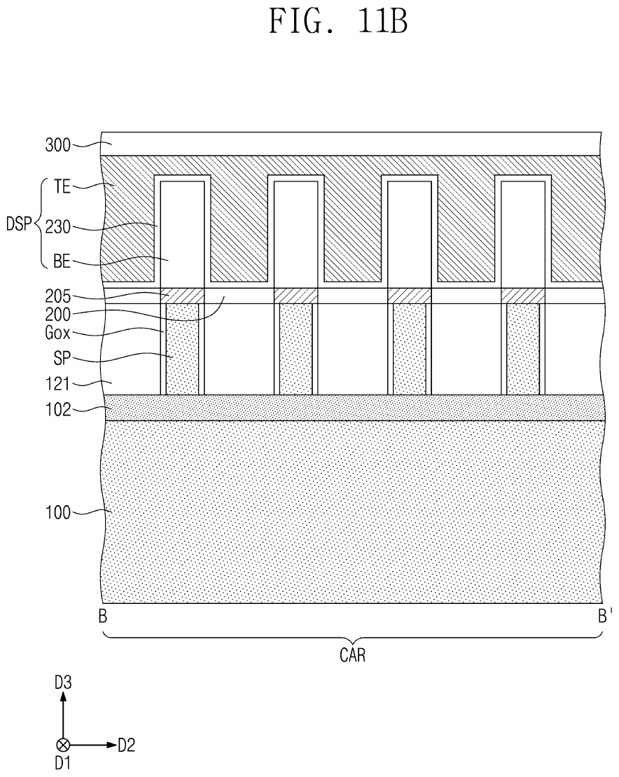

Referring to FIGS. 11A and 11B, a top electrode TE may be formed to cover the capacitor dielectric layer 230. The top electrode TE may fill a space between the bottom electrodes BE. The top electrode TE may further extend in a horizontal direction than the capacitor dielectric layer 230 and the interlayer dielectric layer 200. A data storage pattern DSP may thus be formed which includes the bottom electrodes BE, the capacitor dielectric layer 230, and the top electrode TE.

After that, a first upper dielectric layer 300 may be formed on the cell array region CAR and the connection region CNR of the substrate 100. The first upper dielectric layer 300 may cover the data storage pattern DSP and the second dielectric pattern 123. In an embodiment, a portion of the first upper dielectric layer 300 may be disposed in a space between a bottom surface of the top electrode TE and a top surface of the second dielectric pattern 123.

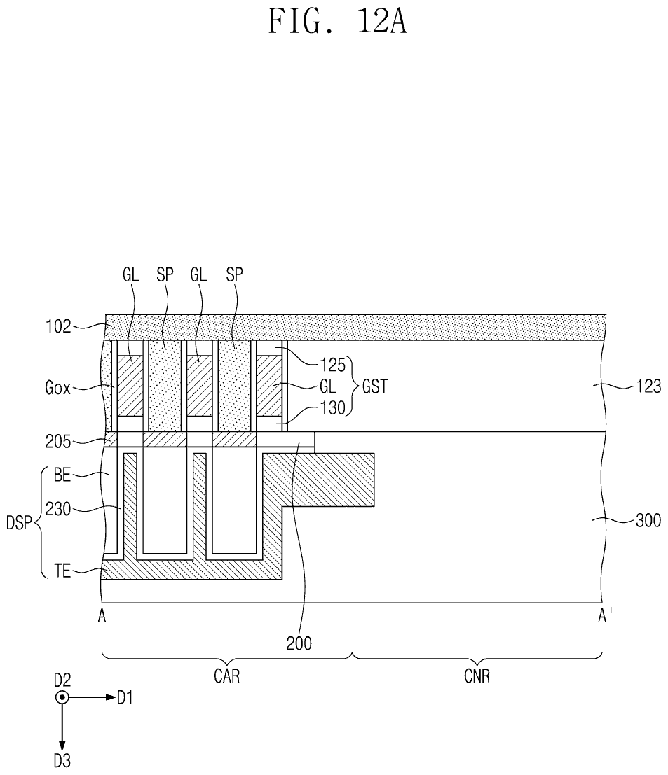

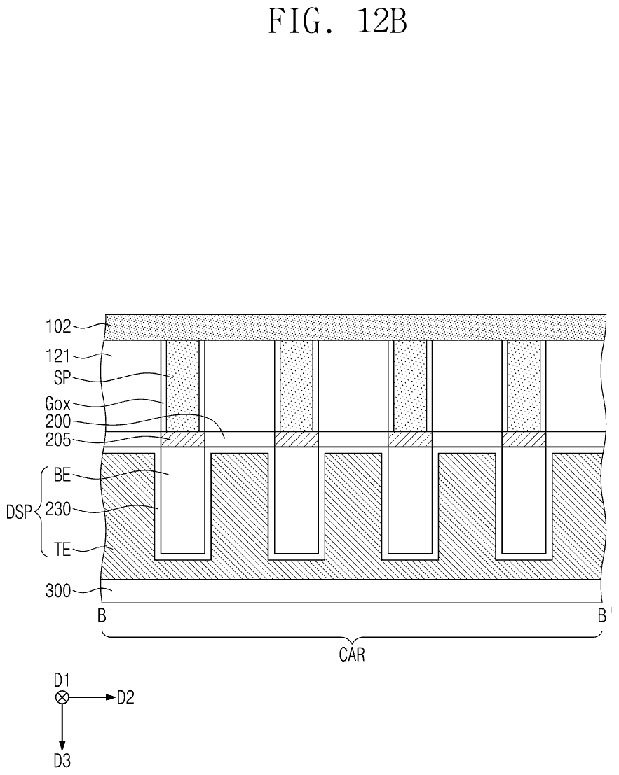

Referring to FIGS. 12A and 12B, a semiconductor memory device may be turned upside down. Thus, the first upper dielectric layer 300 may be positioned at a level lower than that of the substrate 100. In a state where a semiconductor memory device is turned upside down, a polishing process may be performed on the substrate 100. The polishing process may continue until the seed layer 102 is exposed. Therefore, the substrate 100 may be completely removed. The polishing process may include, for example, a chemical mechanical polishing (CMP) process, an etch-back process, or a wet etching process.

As the seed layer 102 has etch selectivity with respect to the substrate 100, the seed layer 102 may serve as a polishing stop layer in the polishing process. As a result, it may be possible to prevent the substrate 100 from remaining on the seed layer 102, or to prevent damage to components (e.g., the vertical channel patterns SP, the first dielectric patterns 121, and the second dielectric pattern 123) below the seed layer 102.

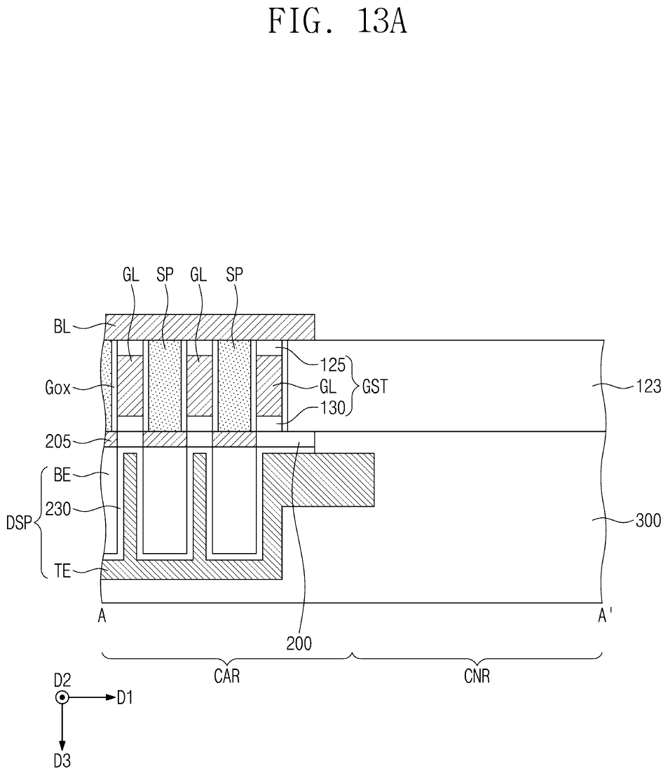

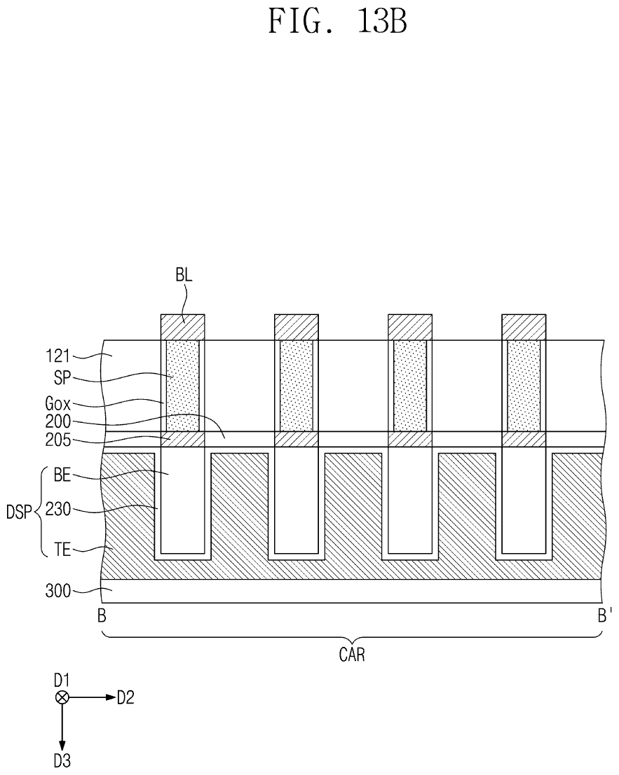

Referring to FIGS. 13A and 13B, the exposed seed layer 102 may be selectively removed. An etching process that selectively removes the seed layer 102 may have a high etch rate for silicon-germanium (SiGe) having a relatively high concentration of germanium (Ge). Thus, only the seed layer 102 may be removed while leaving the vertical channel patterns SP, the first dielectric patterns 121, and the second dielectric pattern 123.

Thereafter, bit lines BL may be formed on the cell array region CAR. The formation of the bit lines BL may include forming a bit line layer, forming a mask pattern on the bit line layer, patterning the bit line layer into the bit lines BL using the mask pattern as an etching mask, and removing the mask pattern. Each of the bit lines BL may extend in the first direction D1. The bit lines BL may be spaced apart from each other in the second direction D2. The bit lines BL may contact the vertical channel patterns SP.

Referring back to FIGS. 5A and 5B, a lower dielectric layer 400 may be formed on the cell array region CAR and the connection region CNR. The lower dielectric layer 400 may cover the bit lines BL, the first dielectric patterns 121, and the second dielectric pattern 123.

According to some embodiments of the present inventive concepts, a subsequent process performed after the formation of the semiconductor layer 104 may cause dopants of the seed layer 102 to diffuse from the seed layer 102 toward the vertical channel patterns SP, the first dielectric patterns 121, and the second dielectric pattern 123. For example, in the process of forming the vertical channel patterns SP, the first dielectric patterns, and the second dielectric pattern 123 performed after the formation of the semiconductor layer 104, the dopant of the seed layer 102 may be diffused toward the vertical channel patterns SP, the first dielectric patterns 121, and the second dielectric pattern 123. Such diffusion of the dopant may occur until the seed layer 102 is removed. The vertical channel patterns SP, the first dielectric patterns 121, and the second dielectric pattern 123 may have concentrations of the dopant substantially the same as that discussed above with reference to FIGS. 6A and 6B.

According to the present inventive concepts, the semiconductor layer 104 with fewer crystal defects may be formed on the doped seed layer 102. The semiconductor layer 104 may be formed into the vertical channel patterns SP. Therefore, the vertical channel patterns SP may be formed with high-quality single-crystalline silicon. In conclusion, a semiconductor memory device may improve in reliability and electrical properties.

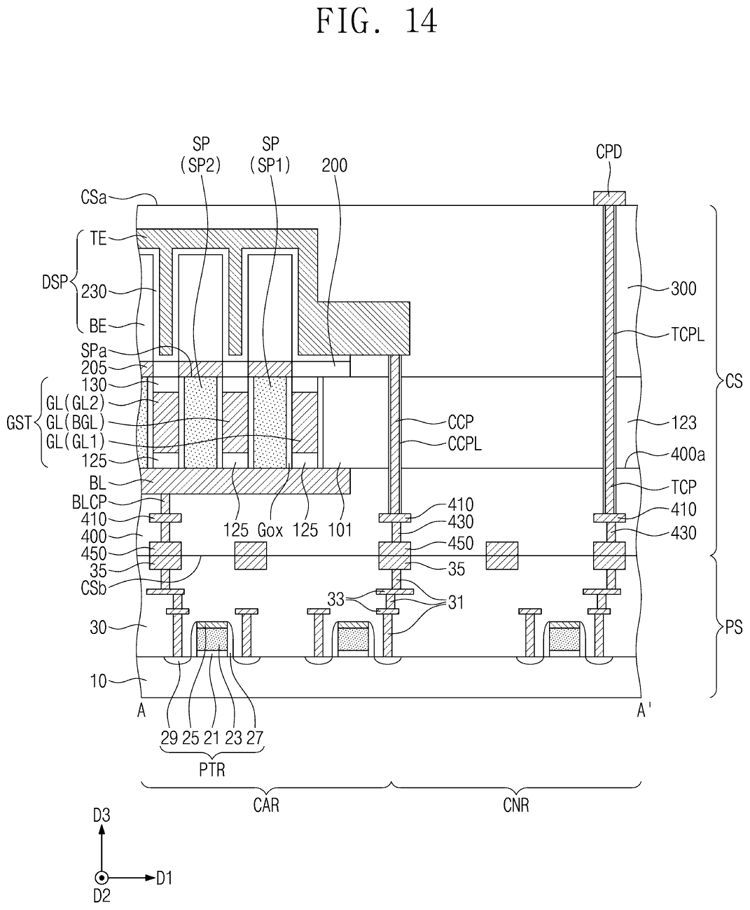

FIGS. 14 to 17 illustrate cross-sectional views taken along line A-A′ of FIG. 4, showing a semiconductor memory device according to some embodiments of the present inventive concepts.

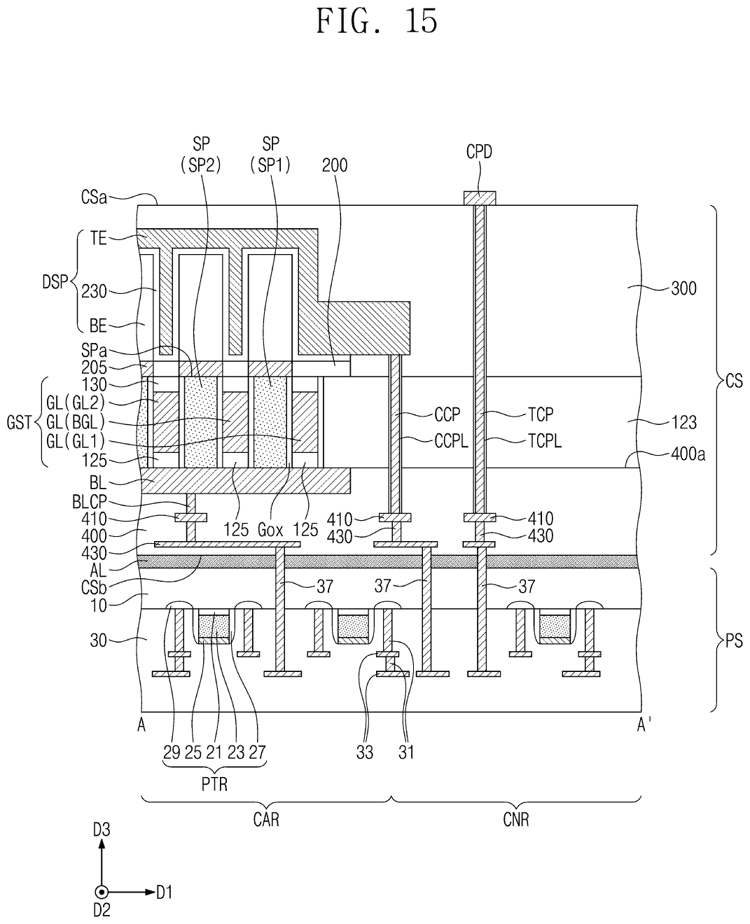

Referring to FIGS. 14 and 15, a semiconductor memory device may further include a peripheral circuit structure PS that is positioned below and vertically overlaps the cell structure CS. The cell structure CS may be electrically connected to the peripheral circuit structure PS. Therefore, the cell structure CS may further include components other than those discussed with reference to FIGS. 4, 5A and 5B, and 6A and 6B.

Referring to FIG. 14, a bit-line contact plug BLCP may be provided in the lower dielectric layer 400. The bit-line contact plug BLCP may be connected to one of the bit lines BL. The bit-line contact plug BLCP may be electrically connected to one of first bonding pads 450 through connection circuit lines 410 and connection contact plugs 430. The connection circuit lines 410 and the connection contact plugs 430 may include a conductive material, such as metal.

A capacitor contact plug CCP may be provided to penetrate a portion of the lower dielectric layer 400 and a portion of the first upper dielectric layer 300, while penetrating the second dielectric pattern 123. The capacitor contact plug CCP may be connected to the top electrode TE of the data storage pattern DSP. The capacitor contact plug CCP may be electrically connected to one of the first bonding pads 450 through the connection circuit lines 410 and the connection contact plugs 430.

A capacitor plug line layer CCPL may be provided to have a uniform thickness that surrounds a lateral surface of the capacitor contact plug CCP. The capacitor plug line layer CCPL may be positioned between the lateral surface of the capacitor contact plug CCP and each of the first upper dielectric layer 300, the second dielectric pattern 123, and the lower dielectric layer 400. According to an embodiment, the capacitor plug line layer CCPL may be omitted.

A connection pad CPD may be provided on the first upper dielectric layer 300. A through contact plug TCP may be provided to have a connection with the connection pad CPD and to penetrate the first upper dielectric layer 300, the second dielectric pattern 123, and a portion of the lower dielectric layer 400. The through contact plug TCP may be electrically connected to one of the first bonding pads 450 through the connection circuit lines 410 and the connection contact plugs 430.

A through plug line layer TCPL may be provided to have a uniform thickness that surrounds a lateral surface of the through contact plug TCP. Through plug line layer TCPL may be positioned between the lateral surface of the through contact plug TCP and each of the first upper dielectric layer 300, the second dielectric pattern 123, and the lower dielectric layer 400. According to an embodiment, the through plug line layer TCPL may be omitted.

In the lower dielectric layer 400, the first bonding pads 450 may be provided adjacent to a bottom surface CSb of the lower dielectric layer 400. The bottom surface CSb of the lower dielectric layer 400 may expose bottom surfaces of the first bonding pads 450. For example, the bottom surface CSb of the lower dielectric layer 400 may be coplanar with the bottom surfaces of the first bonding pads 450.

The peripheral circuit structure PS may be positioned on the bottom surface CSb of the lower dielectric layer 400. The peripheral circuit structure PS may be vertically aligned with the lower dielectric layer 400. The peripheral circuit structure PS may include peripheral circuit transistors PTR on a peripheral substrate 10, peripheral contact plugs 31, peripheral circuit lines 33 electrically connected through the peripheral contact plugs 31 to the peripheral circuit transistors PTR, and a first dielectric layer 30 that surrounds the peripheral circuit transistors PTR, the peripheral contact plugs 31, and the peripheral circuit lines 33.

A peripheral circuit may be constituted by the peripheral circuit transistors PTR, the peripheral contact plugs 31, and the peripheral circuit lines 33. Each of the peripheral circuit transistors PTR may include a peripheral gate dielectric layer 21, a peripheral gate electrode 23, a peripheral capping pattern 25, a peripheral gate spacer 27, and peripheral source/drain regions 29.

The peripheral gate dielectric layer 21 may be positioned between the peripheral gate electrode 23 and the peripheral substrate 10. The peripheral capping pattern 25 may be positioned on the peripheral gate electrode 23. The peripheral gate spacer 27 may cover a sidewall of the peripheral gate dielectric layer 21, a sidewall of the peripheral gate electrode 23, and a sidewall of the peripheral capping pattern 25. The peripheral source/drain regions 29 may be positioned in the peripheral substrate 10 adjacent to opposite sides of the peripheral gate electrode 23.

The peripheral circuit lines 33 may be electrically connected through the peripheral contact plugs 31 to the peripheral circuit transistors PTR. For example, each of the peripheral circuit transistors PTR may be, an NMOS transistor, a PMOS transistor, or a gate-all-around type transistor, but the present inventive concepts are not limited thereto. The peripheral contact plugs 31 and the peripheral circuit lines 33 may include a conductive material, such as metal.

The first dielectric layer 30 may be provided on the peripheral substrate 10. On the peripheral substrate 10, the first dielectric layer 30 may cover the peripheral circuit transistors PTR, the peripheral contact plugs 31, and the peripheral circuit lines 33. The first dielectric layer 30 may be formed as a multi-layer structure. For example, the first dielectric layer 30 may include one or more of silicon oxide, silicon nitride, silicon oxynitride, and low-k dielectric.

The first dielectric layer 30 may be provided therein with second bonding pads 35 adjacent to a top surface of the first dielectric layer 30. The first dielectric layer 30 may not cover top surfaces of the second bonding pads 35. For example, the top surface of the first dielectric layer 30 may be coplanar with those of the second bonding pads 35. The second bonding pads 35 may be electrically connected to the peripheral circuit transistors PTR through the peripheral contact plugs 31 and the peripheral circuit lines 33.

The first bonding pads 450 may contact the second bonding pads 35. The bottom surfaces of the first bonding pads 450 may contact the top surfaces of the second bonding pads 35. The first and second bonding pads 450 and 35 may constitute an intermetallic hybrid bonding. In this description, the term “hybrid bonding” may denote a bonding in which two components of the same kind are merged at an interface therebetween. Thus, the first and second bonding pads 450 and 35 may have a single object without an interface therebetween. For example, the first and second bonding pads 450 and 35 may be integrated into a single object using the intermetallic hybrid bonding. In an embodiment, the first and second bonding pads 450 and 35 may include metal, such as copper (Cu), tungsten (W), aluminum (Al), nickel (Ni), and tin (Sn).

Referring to FIG. 15, an interface layer AL may be formed on the bottom surface CSb of the lower dielectric layer 400. The peripheral circuit structure PS may be positioned on a bottom surface of the interface layer AL. The peripheral circuit structure PS may include peripheral through contacts 37 electrically connected to the peripheral circuit transistors PTR through the peripheral contact plugs 31 and the peripheral circuit lines 33. The peripheral through contacts 37 may penetrate the interface layer AL to have a connection with the connection circuit lines 410 of the cell structure CS. Therefore, the data storage pattern DSP of the cell structure CS may be electrically connected to the peripheral circuit transistors PTR of the peripheral circuit structure PS.

A dielectric layer may be provided between the peripheral substrate 10 and sidewalls of the peripheral through contacts 37. This configuration may insulate the peripheral through contacts 37 and the peripheral substrate 10 from each other.

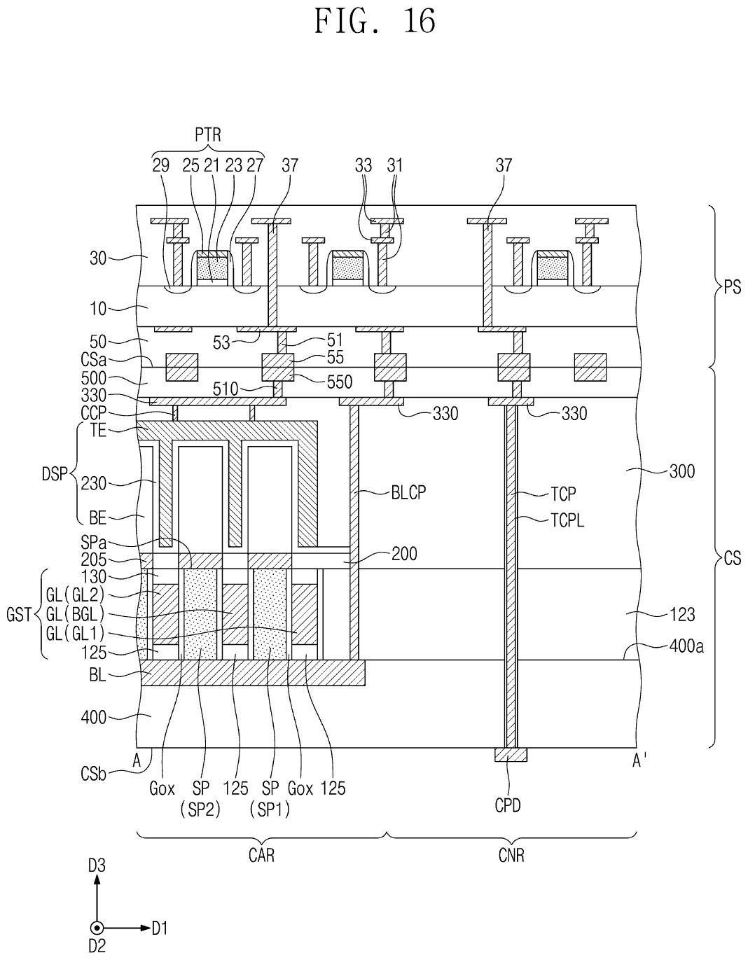

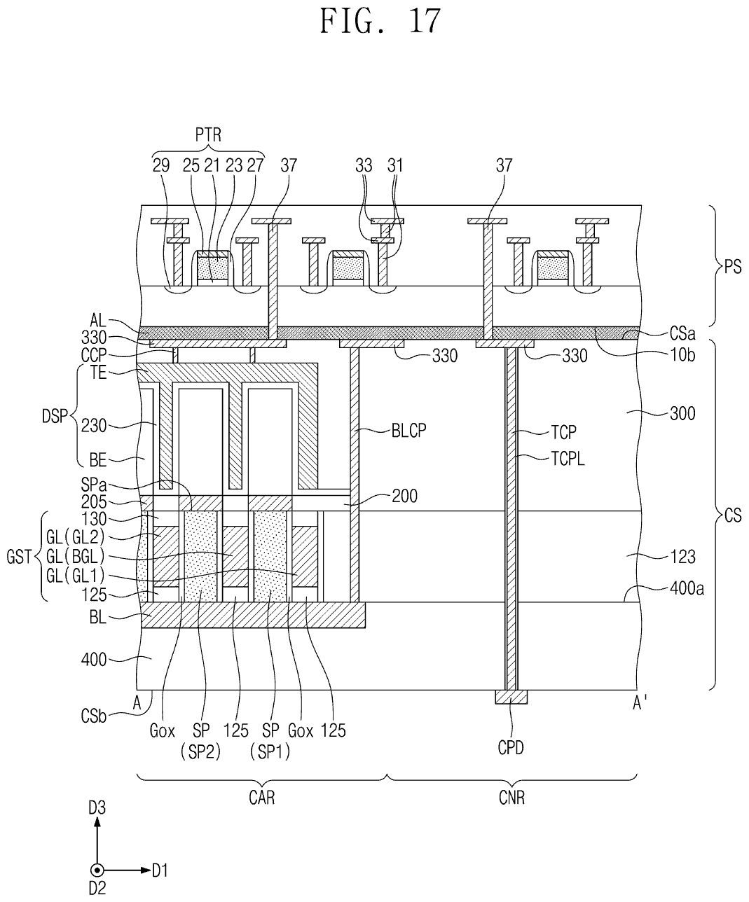

Referring to FIGS. 16 and 17, a semiconductor memory device may further include a peripheral circuit structure PS that is positioned on the cell structure CS and vertically overlaps the cell structure CS. The cell structure CS may be electrically connected to the peripheral circuit structure PS. Therefore, the cell structure CS may further include components other than those discussed with reference to FIGS. 4 to 6B.

Referring to FIG. 16, a capacitor contact plug CCP may be provided in the first upper dielectric layer 300. The capacitor contact plug CCP may be connected to the top electrode TE of the data storage pattern DSP. The capacitor contact plug CCP may be connected to one of upper circuit lines 330.

A bit-line contact plug BLCP may be provided to penetrate the second dielectric pattern 123 and a portion of the first upper dielectric layer 300. The bit-line contact plug BLCP may be connected to one of the bit lines BL and one of the upper circuit lines 330. The bit-line contact plug BLCP may connect the bit line BL to the upper circuit line 330.

A connection pad CPD may be provided on the bottom surface CSb of the lower dielectric layer 400. A through contact plug TCP may be provided to penetrate the lower dielectric layer 400, the second dielectric pattern 123, and a portion of the first upper dielectric layer 300, thereby being connected to the connection pad CPD. The through contact plug TCP may be connected to one of the upper circuit lines 330. A through plug line layer TCPL may be provided to have a uniform thickness that surrounds a lateral surface of the through contact plug TCP.

A second upper dielectric layer 500 may be provided on the first upper dielectric layer 300. The second upper dielectric layer 500 may be provided therein with upper contact plugs 510 and upper bonding pads 550. A top surface CSa of the second upper dielectric layer 500 may not cover top surfaces of the upper bonding pads 550. For example, the top surface CSa of the second upper dielectric layer 500 may be coplanar with the top surfaces of the upper bonding pads 550. The capacitor contact plug CCP, the bit-line contact plug BLCP, and the through contact plug TCP may be electrically connected through the upper contact plugs 510 to the upper bonding pads 550.

The peripheral circuit structure PS may be positioned on the top surface CSa of the second upper dielectric layer 500. The peripheral circuit structure PS may include peripheral through contacts 37 electrically connected to the peripheral circuit transistors PTR through the peripheral contact plugs 31 and the peripheral circuit lines 33.

A second dielectric layer 50 may be provided on a bottom surface of the peripheral substrate 10. The second dielectric layer 50 may include lower contact plugs 51, lower circuit lines 53, and lower bonding pads 55. A bottom surface of the second dielectric layer 50 may not cover bottom surfaces of the lower bonding pads 55. The bottom surface of the second dielectric layer 50 may be coplanar with the bottom surfaces of the lower bonding pads 55. The peripheral through contacts 37 may penetrate the peripheral substrate 10 to come into electrical connection with the lower bonding pads 55 through the lower contact plugs 51 and the lower circuit lines 53.

The lower bonding pads 55 may contact upper bonding pads 550. The bottom surfaces of the lower bonding pads 55 may contact the top surfaces of the upper bonding pads 550. The lower bonding pads 55 and the upper bonding pads 550 may constitute an intermetallic hybrid bonding. For example, the lower and upper bonding pads 55 and 550 may include metal, such as copper (Cu), tungsten (W), aluminum (Al), nickel (Ni), and tin (Sn).

Referring to FIG. 17, an interface layer AL may be provided on the first upper dielectric layer 300. The interface layer AL may be substantially the same as that discussed with reference to FIG. 15.

The peripheral circuit structure PS may be positioned on a top surface of the interface layer AL. The peripheral circuit structure PS may include peripheral through contacts 37 electrically connected to the peripheral circuit transistors PTR through the peripheral contact plugs 31 and the peripheral circuit lines 33. The peripheral through contacts 37 may penetrate the interface layer AL to have a connection with the upper circuit lines 330 of the cell structure CS. Therefore, the data storage pattern DSP of the cell structure CS may be electrically connected to the peripheral circuit transistors PTR of the peripheral circuit structure PS.

Vertical channel patterns according to some embodiments of the present inventive concepts may be formed on a doped seed layer to have fewer crystal defects. A subsequent process may cause dopants to diffuse from the seed layer into the vertical channel patterns and a dielectric pattern. Therefore, the vertical channel patterns may be formed with high-quality single-crystalline silicon. The seed layer may have etch selectivity with respect to a substrate and a semiconductor layer. The seed layer may serve as a stop layer or a polishing stop layer in the procedure for removing the substrate and the semiconductor layer. Therefore, other components may be prevented from being damaged. In conclusion, a semiconductor memory device may improve in reliability and electrical properties.

Although the present invention has been described in connection with the embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A semiconductor memory device, comprising:
a lower dielectric layer that comprises a cell array region and a connection region that extends from the cell array region;
a vertical channel pattern on the cell array region of the lower dielectric layer;
a gate line on a lateral surface of the vertical channel pattern on the cell array region of the lower dielectric layer;
a data storage pattern on the vertical channel pattern on the cell array region of the lower dielectric layer; and
a dielectric pattern on the connection region of the lower dielectric layer,
wherein the vertical channel pattern and the dielectric pattern comprise the same dopant.

2. The semiconductor memory device of claim 1,
wherein the dopant comprises at least one selected from carbon and boron.

3. The semiconductor memory device of claim 1,
wherein a concentration of the dopant decreases in a vertical direction from a bottom surface of the vertical channel pattern toward a top surface of the vertical channel pattern, and
wherein the vertical direction is perpendicular to a top surface of the lower dielectric layer.

4. The semiconductor memory device of claim 1,
wherein the data storage pattern comprises:
a bottom electrode connected to the vertical channel pattern;
a top electrode on the bottom electrode; and
a capacitor dielectric layer between the bottom electrode and the top electrode.

5. The semiconductor memory device of claim 1, further comprising a bit line in the cell array region of the lower dielectric layer,
wherein the bit line is connected to the vertical channel pattern and is spaced apart from the gate line.

6. The semiconductor memory device of claim 1,
wherein a material of the vertical channel pattern is single-crystalline silicon.

7. The semiconductor memory device of claim 1, further comprising a gate dielectric layer between the gate line and the vertical channel pattern.

8. The semiconductor memory device of claim 1,
wherein a bottom surface of the vertical channel pattern and a bottom surface of the dielectric pattern are positioned on the same plane.

9. The semiconductor memory device of claim 1,
wherein the vertical channel pattern has a shape that extends in a vertical direction perpendicular to a top surface of the lower dielectric layer.

10. The semiconductor memory device of claim 1, further comprising a peripheral circuit structure that vertically overlaps the lower dielectric layer,
wherein the peripheral circuit structure comprises a peripheral circuit transistor electrically connected to the data storage pattern.

11. A semiconductor memory device, comprising:
a lower dielectric layer that comprises a cell array region and a connection region that extends from the cell array region;
a plurality of vertical channel patterns on the cell array region of the lower dielectric layer and spaced apart from each other in a first direction and a second direction;
a plurality of gate lines that extend in the second direction and are spaced apart from each other in the first direction;
a first dielectric pattern on the cell array region of the lower dielectric layer and in spaces between the plurality of vertical channel patterns that are adjacent to each other in the second direction; and
a second dielectric pattern on the connection region of the lower dielectric layer,
wherein a material of the plurality of vertical channel patterns is single-crystalline silicon comprising a dopant, and
wherein the dopant comprises at least one selected from carbon and boron.

12. The semiconductor memory device of claim 11,
wherein the first direction and the second direction are parallel to a top surface of the lower dielectric layer, and
wherein each vertical channel pattern of the plurality of vertical channel patterns has a shape that extends in a vertical direction perpendicular to the first direction and the second direction.

13. The semiconductor memory device of claim 11, further comprising a plurality of bit lines in the cell array region of the lower dielectric layer,
wherein the plurality of bit lines extend in the first direction and are spaced apart from each other in the second direction, and
wherein each bit line of the plurality of bit lines are electrically connected to a corresponding vertical channel pattern of the plurality of vertical channel patterns.

14. The semiconductor memory device of claim 11,
wherein the first dielectric pattern and the second dielectric pattern comprise the dopant of the plurality of vertical channel patterns.

15. The semiconductor memory device of claim 11, further comprising a data storage pattern connected to a corresponding vertical channel pattern of the plurality of vertical channel patterns on the cell array region of the lower dielectric layer,
wherein the data storage pattern comprises a bottom electrode, a top electrode, and a capacitor dielectric layer between the bottom electrode and the top electrode.

16. The semiconductor memory device of claim 11,
wherein a bottom surface of each vertical channel pattern of the plurality of vertical channel patterns, a bottom surface of the first dielectric pattern, and a bottom surface of the second dielectric pattern are positioned on the same plane.

17. A semiconductor memory device, comprising:
a peripheral circuit structure that comprises a plurality of peripheral circuit transistors; and
a cell structure that vertically overlaps the peripheral circuit structure,
wherein the cell structure comprises:
a lower dielectric layer that comprises a cell array region and a connection region that extends from the cell array region;
a plurality of bit lines on the cell array region of the lower dielectric layer;
a plurality of vertical channel patterns on the cell array region of the lower dielectric layer and electrically connected to the plurality of bit lines;
a plurality of gate lines in spaces between the plurality of vertical channel patterns on the cell array region of the lower dielectric layer;
a dielectric pattern on the connection region of the lower dielectric layer; and
a data storage pattern connected to a corresponding vertical channel pattern of the plurality of vertical channel patterns,
wherein the plurality of bit lines and the data storage pattern are electrically connected to the plurality of peripheral circuit transistors of the peripheral circuit structure, and
wherein the corresponding vertical channel pattern and the dielectric pattern comprise the same dopant.

18. The semiconductor memory device of claim 17,
wherein the dopant comprises at least one selected from carbon and boron,
wherein a concentration of the dopant deceases in a vertical direction from a bottom surface of the corresponding vertical channel pattern toward a top surface of the corresponding vertical channel pattern, and
wherein the vertical direction is perpendicular to a top surface of the lower dielectric layer.

19. The semiconductor memory device of claim 17,
wherein a bottom surface of the corresponding vertical channel pattern and a bottom surface of the dielectric pattern are positioned on the same plane, and
wherein a material of the corresponding vertical channel pattern is single-crystalline silicon.

20. The semiconductor memory device of claim 17,
wherein the peripheral circuit structure comprises a plurality of first bonding pads,
wherein the cell structure comprises a plurality of second bonding pads, and
wherein each first bonding pad of the plurality of first bonding pads contacts a corresponding second bonding pad of the plurality of second bonding pads to constitute a single object.
